(19) United States
(12) Patent Application Publication
(10) Pub. No.: US 2015/0077188 A1
(43) Pub. Date: Mar. 19, 2015

(54) VOLTAGE FOLLOWER AMPLIFIER

(71) Applicant: LSI CORPORATION, San Jose, CA (US)

(72) Inventor: Sanyi Zhan, Shanghai (CN)

(21) Appl. No.: 14/140,769

(22) Filed: Dec. 26, 2013

(30) Foreign Application Priority Data
Sep. 13, 2013 (CN) 201310615556.7

(51) Int. Cl. H03F 3/16

(52) U.S. Cl. CPC H03F 3/16
USPC 330/307

(57) ABSTRACT

An amplifier circuit includes a first transistor, a second transistor, and a third transistor. The gate of the first transistor receives the input signal to the amplifier. The second transistor's drain terminal is connected to the first source terminal. The second transistor's source terminal is connected to a first supply node. The third transistor's gate terminal is connected to the first transistor's drain terminal via a first node. The third transistor's drain terminal is connected to a second supply node. The third transistor's source terminal is connected to the second transistor's gate terminal via a second node. The amplifier includes first current bias connected between the second node and the first supply node. The amplifier includes a second current bias connected between the first node and the second supply node.

### BACKGROUND

Scaling of integrated circuit processes has led to steadily decreasing power supply voltages. Reducing power supply voltages reduces power consumption of integrated circuits. Reduced power supply voltages also help prevent oxide breakdown that can occur with decreased gate-oxide thicknesses. Reduced power consumption of integrated circuits is particularly important in portable/mobile electronic devices such as cell phones, smartphones, personal digital assistants, and tablet personal computers. Circuits that can be used for lower-power and/or lower supply voltage operation can be used in the design of high-performance integrated circuits.

### SUMMARY

An embodiment of the invention may therefore comprise an amplifier circuit, comprising: a first transistor that has a first gate terminal, a first source terminal, and a first drain terminal. The first gate terminal receives the input signal to the amplifier. The amplifier includes a second transistor having a second gate terminal, a second source terminal, and a second drain terminal. The second drain terminal is connected to the first source terminal. The second source terminal is connected to a first supply node. The amplifier includes a third transistor having a third gate terminal, a third source terminal, and a third drain terminal. The third gate terminal is connected to the first drain terminal via a first node. The third drain terminal is connected to a second supply node. The third source terminal is connected to the second gate terminal via a second node. The amplifier includes first current bias connected between the second node and the first supply node. The amplifier includes a second current bias connected between the first node and the second supply node.

An embodiment of the invention may therefore further comprise an amplifier, comprising: a first p-channel field effect transistor (PFET) having a first gate terminal, a first source terminal, and a first drain terminal. The first gate terminal is to receive an input signal to the amplifier. The first source terminal connected to an output node that is to provide an output signal of the amplifier. The first drain terminal connected to a first node. The amplifier includes a second PFET having a second gate terminal, a second source terminal, and a second drain terminal. The second drain terminal is connected to the output node. The second source terminal is connected to a positive supply node. The second gate terminal is connected to a second node. The amplifier includes a third PFET having a third gate terminal, a third source terminal, and a third drain terminal. The third gate terminal is connected to the first node. The third drain terminal is connected to a negative supply node. The third source terminal is connected to the second node. The amplifier includes a first current bias to conduct a first bias current from the positive supply node to the second node. The amplifier includes a second current bias to conduct a second bias current from the first node to the negative supply node.

An embodiment of the invention may therefore further comprise an amplifier, comprising: a first n-channel field effect transistor (NFET) having a first gate terminal, a first source terminal, and a first drain terminal. The first gate terminal is to receive an input signal to the amplifier. The first source terminal is connected to an output node that is to provide an output signal of the amplifier. The first drain terminal is connected to a first node. The amplifier includes second NFET having a second gate terminal, a second source terminal, and a second drain terminal. The second drain terminal is connected to the output node. The second source terminal is connected to a negative supply node. The second gate terminal is connected to a second node. The amplifier includes a third NFET having a third gate terminal, a third source terminal, and a third drain terminal. The third gate terminal is connected to the first node. The third drain terminal is connected to a positive supply node. The third source terminal is connected to the second node. The amplifier includes a first current bias to conduct a first bias current from the second node to the negative supply node. The amplifier includes second current bias to conduct a second bias current from the positive supply node to the first node.

### BRIEF DESCRIPTION OF THE DRAWINGS

FIG. 1 is a circuit diagram of a p-channel FET implementation of a super source follower.

FIG. 2 is a circuit diagram of an n-channel FET implementation of a super source follower.

FIG. 3 is a circuit diagram of a field-effect transistor biased p-channel FET implementation of a super source follower.

FIG. 4 is a circuit diagram of field-effect transistor biased n-channel FET implementation of a super source follower.

FIG. 5 is a block diagram of a computer system.

### DETAILED DESCRIPTION OF THE EMBODIMENTS

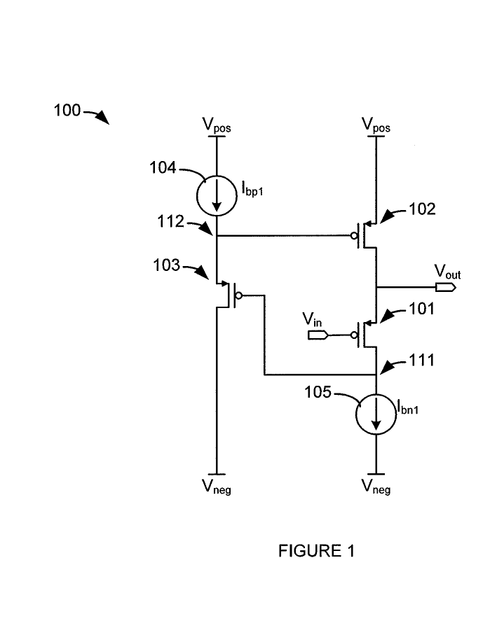

FIG. 1 is a circuit diagram of a p-channel FET implementation of a super source follower. In FIG. 1, source follower 100 comprises p-channel field-effect transistor (PFET) 101, PFET 102, PFET 103, current bias 104, and current bias 105. A first terminal of current bias 105 is connected to a first node 111. A second terminal of current bias 105 is connected to a negative supply voltage, V_{neg}. Current bias 105 conduct a bias current, I_{bn1}, from the first node 111 to the negative supply voltage V_{neg}. A first terminal of current bias 104 is connected to a positive supply voltage, Vₚₒₛ. A second terminal of current bias 104 is connected to a second node 112. Current bias 104 conducts a bias current, I_{bp1}, from the positive supply voltage Vₚₒₛ to the second node 112.

The input to source follower 100 is at node Vᵢₙ. Vᵢₙ is connected to the gate of PFET 101. The drain of PFET 101 is connected to the first node 111. The source of PFET 101 is connected to the output node of source follower 100, Vₒᵤₜ. The source of PFET 102 is connected to the positive supply voltage, Vₚₒₛ. The drain of PFET 102 is connected to Vₒᵤₜ. The gate of PFET 102 is connected to the second node 112. The source of PFET 103 is connected to the second node 112. The gate of PFET 103 is connected to the first node 111. The drain of PFET 103 is connected to the negative supply voltage, V_{neg}.

Qualitatively, when PFET 101 is biased in saturation, source follower 100 functions as follows: (1) a rise in the voltage at Vᵢₙ causes PFET 101 to conduct less current; (2) this results in the voltage at the first node 111 dropping and the voltage at the output node (Vₒᵤₜ) rising; (3) the lower voltage at the first node 111 causes PFET 103 to conduct more current; (4) when PFET 103 conducts more current, the voltage at the second node 112 is reduced; (5) the reduced voltage at the second node 112 causes PFET 102 to conduct more current; (6) the increased current through PFET 102 reinforces the voltage rise at the output node Vₒᵤₜ.

As should be understood from FIG. 1, the gate of PFET 101 is connected to the input signal Vᵢₙ. The source of PFET 101 is connected to the output terminal Vₒᵤₜ. Thus, PFET 101 and PFET 102 constitute a super transconductance loop. The equivalent transconductance of this super transconductance loop is equal to the product of transconductances of PFET 101 and PFET 102 and the equivalent resistance of current bias 105.

In an embodiment, the sizes (i.e., width-to-length ratios) of PFET 101 and PFET 102 are selected such that the transconductance of PFET 102 is high and the transconductance of PFET 102 relatively low. In this way, the size of PFET 101 can be kept small. A small size for PFET 101 improves (increases) the bandwidth of source follower 100 because the parasitic capacitance of PFET 101 is relatively smaller.

PFET 103 and current bias 104 help to shift the drain voltage of PFET 101 down by a gate-to-source voltage of PFET 103. This allows a large W/L ratio of PFET 102 and a small gate-to-source voltage of PFET 102 to be used and still assure the operation region of PFET 101 in saturation. Since current bias 105 conducts a (nearly) constant DC current, and this current is the drain-to-source current of PFET 101, a lower drain voltage of PFET 101 helps increase the output signal swing. Accordingly, the transconductance of PFET 101 can be made to be a nearly a constant value no matter how the load varies. If source follower 100 is used inside a feedback loop, the (near) constant transconductance of source follower 100 makes the design of a stable feedback loop easier. It should also be understood that in some configuration, first node 111 can be used as an output node for circuit 100.

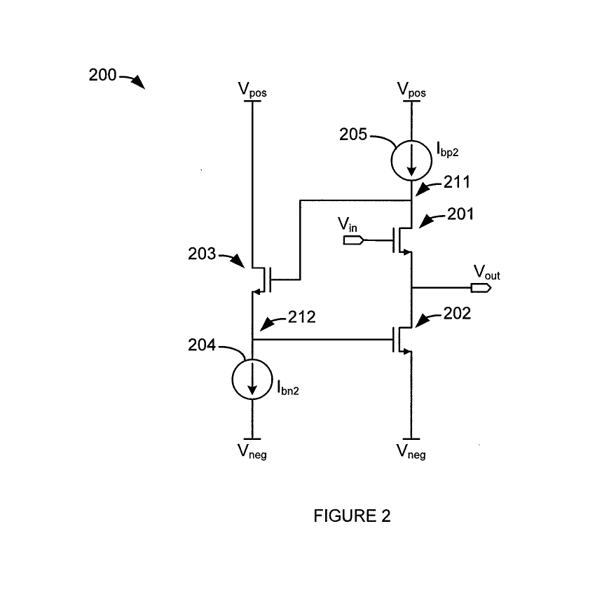

FIG. 2 is a circuit diagram of an n-channel FET implementation of a super source follower. In FIG. 2, source follower 200 comprises n-channel field-effect transistor (NFET) 201, NFET 202, NFET 203, current bias 204, and current bias 205. A first terminal of current bias 205 is connected to a first node 211. A second terminal of current bias 205 is connected to a positive supply voltage, Vₚₒₛ. Current bias 205 conduct a bias current, I_{bp2}, from the positive supply voltage Vₚₒₛ to the first node 211. A first terminal of current bias 204 is connected to a negative supply voltage, V_{neg}. A second terminal of current bias 204 is connected to a second node 212. Current bias 204 conducts a bias current, I_{bn1}, from the second node 212 to the negative supply voltage V_{neg}.

The input to source follower 200 is at node Vᵢₙ. Vᵢₙ is connected to the gate of NFET 201. The drain of NFET 201 is connected to the first node 211. The source of NFET 201 is connected to the output node of source follower 200, Vₒᵤₜ. The source of NFET 202 is connected to the negative supply voltage, V_{neg}. The drain of NFET 202 is connected to Vₒᵤₜ. The gate of NFET 202 is connected to the second node 212. The source of NFET 203 is connected to the second node 212. The gate of NFET 203 is connected to the first node 211. The drain of NFET 203 is connected to the positive supply voltage, Vₚₒₛ.

Qualitatively, when NFET 201 is biased in saturation, source follower 200 functions as follows: (1) a rise in the voltage at Vᵢₙ causes NFET 201 to conduct more current; (2) this results in the voltage at the first node 211 dropping and the voltage at the output node (Vₒᵤₜ) rising; (3) the lower voltage at the first node 211 causes NFET 203 to conduct less current; (4) when NFET 203 conducts less current, the voltage at the second node 212 is reduced; (5) the reduced voltage at the second node 212 causes NFET 202 to conduct less current; (6) the decreased current through NFET 202 reinforces the voltage rise at the output node Vₒᵤₜ.

As should be understood from FIG. 2, the gate of NFET 201 is connected to the input signal Vᵢₙ. The source of NFET 201 is connected to the output terminal Vₒᵤₜ. Thus, NFET 201 and NFET 202 constitute a super transconductance loop. The equivalent transconductance of this super transconductance loop is equal to the product of transconductances of NFET 201 and NFET 202 and the equivalent resistance of current bias 205.

In an embodiment, the sizes (i.e., width-to-length ratios) of NFET 201 and NFET 202 are selected such that the transconductance of NFET 202 is high and the transconductance of NFET 201 relatively low. In this way, the size of NFET 201 can be kept small. A small size for NFET 201 improves (increases) the bandwidth of source follower 200 because the parasitic capacitance of NFET 201 is relatively smaller.

NFET 203 and current bias 204 help to shift the drain voltage of NFET 201 up by a gate-to-source voltage of NFET 203. This allows a large W/L ratio of NFET 202 and a small gate-to-source voltage of NFET 202 to be used and still assure the operation region of NFET 201 in saturation. Since current bias 205 conducts a (nearly) constant DC current, and this current is the drain-to-source current of NFET 201, a higher drain voltage of NFET 201 helps increase the output signal swing. Accordingly, the transconductance of NFET 201 can be made to be a nearly a constant value no matter how the load varies. If source follower 200 is used inside a feedback loop, the (near) constant transconductance of source follower 200 makes the design of a stable feedback loop easier. It should also be understood that in some configuration, first node 211 can be used as an output node for circuit 200.

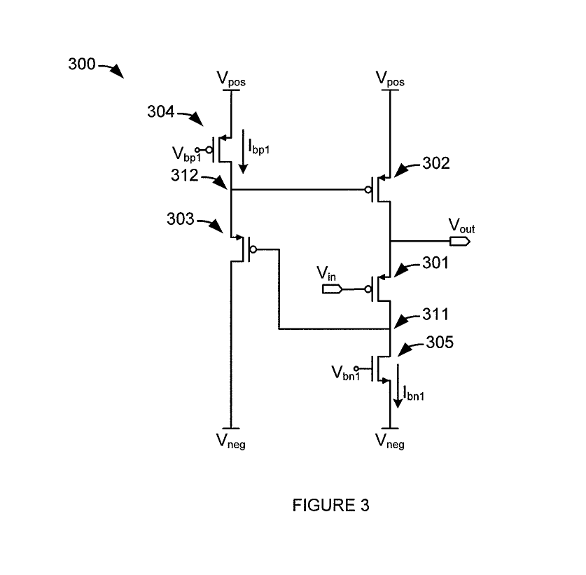

FIG. 3 is a circuit diagram of a field-effect transistor biased p-channel FET implementation of a super source follower. In FIG. 3, source follower 300 comprises PFET 301, PFET 302, PFET 303, PFET 304, and NFET 305. The gate of NFET 305 is connected to a bias voltage V_{bn1}. The drain of NFET 305 is connected to a first node 311. The source of NFET 305 is connected to a negative supply voltage, V_{neg}. V_{bn1} biases NFET 305 to conduct a bias current, I_{bn1}, from the first node 311 to the negative supply voltage V_{neg}. Bias voltage V_{bn1} may be created by a current mirror configuration. The gate of PFET 304 is connected to a bias voltage V_{bp1}. The source of PFET 304 is connected to a positive supply voltage, Vₚₒₛ. The drain of PFET 304 is connected to a second node 312. V_{bp1} biases PFET 304 to conduct a bias current, I_{bp1}, from the positive supply voltage Vₚₒₛ to the second node 312. Bias voltage V_{bp1} may be created by a current mirror configuration.

The input to source follower 300 is at node Vᵢₙ. Vᵢₙ is connected to the gate of PFET 301. The drain of PFET 301 is connected to the first node 311. The source of PFET 301 is connected to the output node of source follower 300, Vₒᵤₜ. The source of PFET 302 is connected to the positive supply voltage, Vₚₒₛ. The drain of PFET 302 is connected to Vₒᵤₜ. The gate of PFET 302 is connected to the second node 312. The source of PFET 303 is connected to the second node 312. The gate of PFET 303 is connected to the first node 311. The drain of PFET 303 is connected to the negative supply voltage, V_{neg}.

Qualitatively, when PFET 301 is biased in saturation, source follower 300 functions as follows: (1) a rise in the voltage at Vᵢₙ causes PFET 301 to conduct less current; (2) this results in the voltage at the first node 311 dropping and the voltage at the output node (Vₒᵤₜ) rising; (3) the lower voltage at the first node 311 causes PFET 303 to conduct more current; (4) when PFET 303 conducts more current, the voltage at the second node 312 is reduced; (5) the reduced voltage at the second node 312 causes PFET 302 to conduct more current; (6) the increased current through PFET 302 reinforces the voltage rise at the output node Vₒᵤₜ.

As should be understood from FIG. 3, the gate of PFET 301 is connected to the input signal Vᵢₙ. The source of PFET 301 is connected to the output terminal Vₒᵤₜ. Thus, PFET 301 and PFET 302 constitute a super transconductance loop. The equivalent transconductance of this super transconductance loop is equal to the product of transconductances of PFET 301 and PFET 302 and the drain-to-source resistance of NFET 305.

In an embodiment, the sizes (i.e., width-to-length ratios) of PFET 301 and PFET 302 are selected such that the transconductance of PFET 302 is high and the transconductance of PFET 302 relatively low. In this way, the size of PFET 301 can be kept small. A small size for PFET 301 improves (increases) the bandwidth of source follower 300 because the parasitic capacitance of PFET 301 is relatively smaller.

PFET 303 and PFET 304 help to shift the drain voltage of PFET 301 down by a gate-to-source voltage of PFET 303. This allows a large W/L ratio of PFET 302 and a small gate-to-source voltage of PFET 302 to be used and still assure the operation region of PFET 301 in saturation. Since NFET 305 conducts a (nearly) constant DC current, and this current is the drain-to-source current of PFET 301, a lower drain voltage of PFET 301 helps increase the output signal swing. Accordingly, the transconductance of PFET 301 can be made to be a nearly a constant value no matter how the load varies. If source follower 300 is used inside a feedback loop, the (near) constant transconductance of source follower 300 makes the design of a stable feedback loop easier. It should also be understood that in some configuration, first node 311 can be used as an output node for circuit 300.

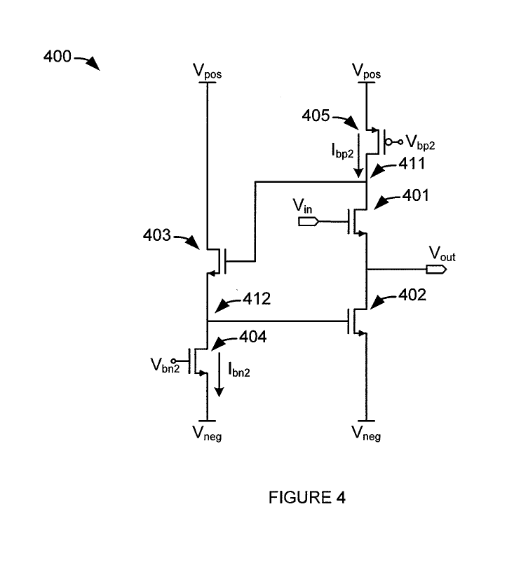

FIG. 4 is a circuit diagram of field-effect transistor biased n-channel FET implementation of a super source follower. In FIG. 4, source follower 400 comprises NFET 401, NFET 402, NFET 403, NFET 404, and NFET 405. The gate of PFET 405 is connected to a bias voltage V_{bp2}. The drain of PFET 405 405 is connected to a first node 411. The source of PFET 405 is connected to a positive supply voltage, Vₚₒₛ. V_{bp2} biases PFET 405 to conduct a bias current, I_{bp2}, from the positive supply voltage Vₚₒₛ to the first node 411. Bias voltage V_{bp2} may be created by a current mirror configuration. The gate of NFET 404 is connected to a bias voltage V_{bn2}. The source of NFET 404 is connected to a negative supply voltage, V_{neg}. The drain of NFET 404 is connected to a second node 412. V_{bn2} biases NFET 404 to conduct a bias current, I_{bn1}, from the second node 412 to the negative supply voltage V_{neg}. Bias voltage V_{bn2} may be created by a current mirror configuration.

The input to source follower 400 is at node Vᵢₙ. Vᵢₙ is connected to the gate of NFET 401. The drain of NFET 401 is connected to the first node 411. The source of NFET 401 is connected to the output node of source follower 400, Vₒᵤₜ. The source of NFET 402 is connected to the negative supply voltage, V_{neg}. The drain of NFET 402 is connected to Vₒᵤₜ. The gate of NFET 402 is connected to the second node 412. The source of NFET 403 is connected to the second node 412. The gate of NFET 403 is connected to the first node 411. The drain of NFET 403 is connected to the positive supply voltage, Vₚₒₛ.

Qualitatively, when NFET 401 is biased in saturation, source follower 400 functions as follows: (1) a rise in the voltage at \lᵢₙ causes NFET 401 to conduct more current; (2) this results in the voltage at the first node 411 dropping and the voltage at the output node (Vₒᵤₜ) rising; (3) the lower voltage at the first node 411 causes NFET 403 to conduct less current; (4) when NFET 403 conducts less current, the voltage at the second node 412 is reduced; (5) the reduced voltage at the second node 412 causes NFET 402 to conduct less current; (6) the decreased current through NFET 402 reinforces the voltage rise at the output node Vₒᵤₜ.

As should be understood from FIG. 4, the gate of NFET 401 is connected to the input signal Vᵢₙ. The source of NFET 401 is connected to the output terminal Vₒᵤₜ. Thus, NFET 401 and NFET 402 constitute a super transconductance loop. The equivalent transconductance of this super transconductance loop is equal to the product of transconductances of NFET 401 and NFET 402 and the equivalent resistance of current bias 405.

In an embodiment, the sizes (i.e., width-to-length ratios) of NFET 401 and NFET 402 are selected such that the transconductance of NFET 402 is high and the transconductance of NFET 402 relatively low. In this way, the size of NFET 401 can be kept small. A small size for NFET 401 improves (increases) the bandwidth of source follower 400 because the parasitic capacitance of NFET 401 is relatively smaller.

NFET 403 and NFET 404 help to shift the drain voltage of NFET 401 up by a gate-to-source voltage of NFET 403. This allows a large W/L ratio of NFET 402 and a small gate-to-source voltage of NFET 402 to be used and still assure the operation region of NFET 401 in saturation. Since PFET 405 conducts a (nearly) constant DC current, and this current is the drain-to-source current of NFET 401, a higher drain voltage of NFET 401 helps increase the output signal swing. Accordingly, the transconductance of NFET 401 can be made to be a nearly a constant value no matter how the load varies. If source follower 400 is used inside a feedback loop, the (near) constant transconductance of source follower 400 makes the design of a stable feedback loop easier. It should also be understood that in some configuration, first node 411 can be used as an output node for circuit 400.

It should be understood that source followers 100, 200, 300, and 400 can be designed to achieve high transconductances, low output impedance (e.g., less than 1 ohm), high bandwidth, and a large output signal swing simultaneously. This can be contrasted with a “flipped voltage follower” which achieves an output impedance in the range of 20 to 200 ohms and has an output signal swing that is limited to a small voltage range.

The circuits, systems and devices described above may be implemented in computer systems, or stored by computer systems. Descriptions of the circuits described above may also be stored on a computer readable medium. Devices, circuits, and systems described herein may be implemented using computer-aided design tools available in the art, and embodied by computer-readable files containing software descriptions of such circuits. This includes, but is not limited to one or more elements of source follower 100, source follower 200, source follow 300, source follower 400 and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

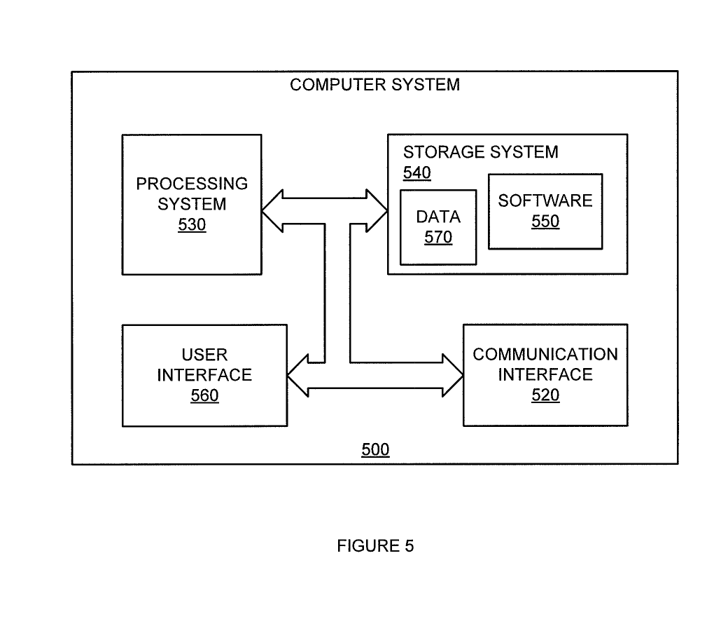

FIG. 5 illustrates a block diagram of a computer system. Computer system 500 includes communication interface 520, processing system 530, storage system 540, and user interface 560. Processing system 530 is operatively coupled to storage system 540. Storage system 540 stores software 550 and data 570. Storage system 540 may include one or more of source follower 100, source follower 200, source follower 300, and/or source follower 400. Processing system 530 is operatively coupled to communication interface 520 and user interface 560. Computer system 500 may comprise a programmed general-purpose computer. Computer system 500 may include a microprocessor. Computer system 500 may comprise programmable or special purpose circuitry. Computer system 500 may be distributed among multiple devices, processors, storage, and/or interfaces that together comprise elements 520-570.

Communication interface 520 may comprise a network interface, modem, port, bus, link, transceiver, or other communication device. Communication interface 520 may be distributed among multiple communication devices. Processing system 530 may comprise a microprocessor, microcontroller, logic circuit, or other processing device. Processing system 530 may be distributed among multiple processing devices. User interface 560 may comprise a keyboard, mouse, voice recognition interface, microphone and speakers, graphical display, touch screen, or other type of user interface device. User interface 560 may be distributed among multiple interface devices. Storage system 540 may comprise a disk, tape, integrated circuit, RAM, ROM, EEPROM, flash memory, network storage, server, or other memory function. Storage system 540 may include computer readable medium. Storage system 540 may be distributed among multiple memory devices.

Processing system 530 retrieves and executes software 550 from storage system 540. Processing system may retrieve and store data 570. Processing system may also retrieve and store data via communication interface 520. Processing system 550 may create or modify software 550 or data 570 to achieve a tangible result. Processing system may control communication interface 520 or user interface 570 to achieve a tangible result. Processing system may retrieve and execute remotely stored software via communication interface 520.

Software 550 and remotely stored software may comprise an operating system, utilities, drivers, networking software, and other software typically executed by a computer system. Software 550 may comprise an application program, applet, firmware, or other form of machine-readable processing instructions typically executed by a computer system. When executed by processing system 530, software 550 or remotely stored software may direct computer system 500 to operate as described herein.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. An amplifier circuit, comprising:
a first transistor having a first gate terminal, a first source terminal, and a first drain terminal, said first gate terminal receiving an input signal to said amplifier;
a second transistor having a second gate terminal, a second source terminal, and a second drain terminal, said second drain terminal connected to said first source terminal, said second source terminal connected to a first supply node; and,
a third transistor having a third gate terminal, a third source terminal, and a third drain terminal, said third gate terminal connected to said first drain terminal via a first node, said third drain terminal connected to a second supply node, said third source terminal connected to said second gate terminal via a second node, a first current bias connected between said second node and said first supply node, a second current bias connected between said first node and said second supply node.

2. The amplifier of claim 1, wherein said first source terminal provides an output signal of said amplifier.

3. The amplifier of claim 1, wherein said first transistor, said second, transistor, and said third transistor are n-channel field effect transistors.

4. The amplifier of claim 1, wherein said first transistor, said second, transistor, and said third transistor are p-channel field effect transistors.

5. The amplifier of claim 1, wherein said first current bias comprises a first constant current source element.

6. The amplifier of claim 5, wherein said first constant current source element includes a fourth transistor having a fourth gate terminal, a fourth source terminal, and a fourth drain terminal, said fourth gate terminal receiving a first bias voltage, said fourth source terminal connected to said first supply node, and said fourth drain terminal is connected to said second node.

7. The amplifier of claim 6, wherein said second current bias comprises a second constant current source element.

8. The amplifier of claim 7, wherein said second constant current source element includes a fifth transistor having a fifth gate terminal, a fifth source terminal, and a fifth drain terminal, said fifth gate terminal receiving a second bias voltage, said fifth source terminal connected to said second supply node, and said fifth drain terminal is connected to said first node.

9. An amplifier, comprising:
a first p-channel field effect transistor (PFET) having a first gate terminal, a first source terminal, and a first drain terminal, said first gate terminal receiving an input signal to said amplifier, said first source terminal connected to an output node that provides an output signal of said amplifier, said first drain terminal connected to a first node;
a second PFET having a second gate terminal, a second source terminal, and a second drain terminal, said second drain terminal connected to said output node, said second source terminal connected to a positive supply node, said second gate terminal connected to a second node;
a third PFET having a third gate terminal, a third source terminal, and a third drain terminal, said third gate terminal connected to said first node, said third drain terminal connected to a negative supply node, said third source terminal connected to said second node;
a first current bias that conducts a first bias current from said positive supply node to said second node; and, a second current bias that conducts a second bias current from said first node to said negative supply node.

10. The amplifier of claim 9, wherein said first current bias comprises a first constant current source element and said second current bias comprises a second constant current source element.

11. The amplifier of claim 5, wherein said first constant current source element includes a fourth PFET having a fourth gate terminal, a fourth source terminal, and a fourth drain terminal, said fourth gate terminal receiving a first bias voltage, said fourth source terminal connected to said positive supply node, and said fourth drain terminal is connected to said second node.

12. The amplifier of claim 5, wherein said second constant current source element includes a re-channel field effect transistor (NFET) having a fourth gate terminal, a fourth source terminal, and a fourth drain terminal, said fourth gate terminal receiving a first bias voltage, said fourth source terminal connected to said negative supply node, and said fourth drain terminal is connected to said first node.

13. The amplifier of claim 5, wherein said first constant current source element includes a fourth PFET having a fourth gate terminal, a fourth source terminal, and a fourth drain terminal, said fourth gate terminal receiving a first bias voltage, said fourth source terminal connected to said positive supply node, and said fourth drain terminal is connected to said second node, said second constant current source element including an n-channel field effect transistor (NFET) having a fifth gate terminal, a fifth source terminal, and a fifth drain terminal, said fifth gate terminal receiving a second bias voltage, said fifth source terminal connected to said negative supply node, and said fifth drain terminal is connected to said first node.

14. An amplifier, comprising:
a first n-channel field effect transistor (NFET) having a first gate terminal, a first source terminal, and a first drain terminal, said first gate terminal receiving an input signal to said amplifier, said first source terminal connected to an output node that provides an output signal of said amplifier, said first drain terminal connected to a first node;
a second NFET having a second gate terminal, a second source terminal, and a second drain terminal, said second drain terminal connected to said output node, said second source terminal connected to a negative supply node, said second gate terminal connected to a second node;
a third NFET having a third gate terminal, a third source terminal, and a third drain terminal, said third gate terminal connected to said first node, said third drain terminal connected to a positive supply node, said third source terminal connected to said second node;
a first current bias that conducts a first bias current from said second node to said negative supply node; and,
a second current bias that conducts a second bias current from said positive supply node to said first node.

15. The amplifier of claim 14, wherein said first current bias comprises a first constant current source element and said second current bias comprises a second constant current source element.

16. The amplifier of claim 15, wherein said first constant current source element includes a fourth NFET having a fourth gate terminal, a fourth source terminal, and a fourth drain terminal, said fourth gate terminal receiving a first bias voltage, said fourth source terminal connected to said negative supply node, and said fourth drain terminal is connected to said second node.

17. The amplifier of claim 15, wherein said second constant current source element includes a p-channel field effect transistor (PFET) having a fourth gate terminal, a fourth source terminal, and a fourth drain terminal, said fourth gate terminal receiving a first bias voltage, said fourth source terminal connected to said positive supply node, and said fourth drain terminal is connected to said first node.

18. The amplifier of claim 15, wherein said first constant current source element includes a fourth PFET having a fourth gate terminal, a fourth source terminal, and a fourth drain terminal, said fourth gate terminal receiving a first bias voltage, said fourth source terminal connected to said negative supply node, and said fourth drain terminal is connected to said second node, said second constant current source element including an n-channel field effect transistor (NFET) having a fifth gate terminal, a fifth source terminal, and a fifth drain terminal, said fifth gate terminal receiving a second bias voltage, said fifth source terminal connected to said positive supply node, and said fifth drain terminal is connected to said first node.
